(19) United States
(12) Patent Application Publication
(10) Pub. No.: US 2025/0194378 A1
(43) Pub. Date: Jun. 12, 2025

(54) DISPLAY DEVICE

(71) Applicant: Samsung Display Co., Ltd., Yongin-Si (KR)

(72) Inventors: DONGHYEOK LEE, Yongin-si (KR); KWANHEE LEE, Yongin-si (KR); MOOSOON KO, Yongin-si (KR); Jonghwan Shin, Yongin-si (KR); YONGHO YANG, Yongin-si (KR); YURI OH, Yongin-si (KR); KI-BOK YOO, Yongin-si (KR); JONG CHAN LEE, Yongin-si (KR); JIN-SUK LEE, Yongin-si (KR)

(21) Appl. No.: 18/977,502

(22) Filed: Dec. 11, 2024

(30) Foreign Application Priority Data
Dec. 12, 2023 (KR) 10-2023-0179491

(51) Int. Cl. H10K 59/80; H10H 29/45; H10H 29/854; H10K 59/127

(52) U.S. Cl. CPC H10K 59/8723; H10H 29/45; H10H 29/854; H10K 59/127

(57) ABSTRACT

A display device is disclosed that includes a first substrate, a spacer disposed on the first substrate and including a side surface having a reverse tapered shape in a cross-sectional view, a protection pattern disposed on the spacer, and a second substrate disposed on the protection pattern and spaced apart from the first substrate to define a space.

### CROSS-REFERENCE TO RELATED APPLICATION(S)

This application claims priority under 35 USC § 119 to Korean Patent Application No. 10-2023-0179491 filed on Dec. 12, 2023, in the Korean Intellectual Property Office (KIPO), the entire disclosure of which is incorporated by reference herein.

### BACKGROUND

### 1. Field

Embodiments relate to a display device and an electronic device.

### 2. Description of the Related Art

If impurities such as moisture, oxygen, or the like are introduced into a display device from outside, a lifespan of a transistor included in the display device may be shortened, and luminous efficiency of a light emitting element included in the display device may be reduced.

Accordingly, the display device may be encapsulated to isolate an inside of the display device from the outside and prevent the impurities such as moisture or the like from penetrating. For example, the display device may include a substrate and an encapsulation substrate that forms a cover or cap on the substrate. The substrate and the encapsulation substrate may be integrally coupled by a sealing member.

### SUMMARY

Embodiments may provide a display device with improved display quality.

Embodiments may provide an electronic device including the display device.

A display device according to an embodiment of the present disclosure includes a first substrate, a spacer disposed on the first substrate and including a side surface having a reverse tapered shape in a cross-sectional view, a protection pattern disposed on the spacer, and a second substrate disposed on the protection pattern and spaced apart from the first substrate to define a space.

In an embodiment, the protection pattern may cover an upper surface and the side surface of the spacer.

In an embodiment, the space may be filled with a filler.

In an embodiment, the protection pattern may include an inorganic material.

In an embodiment, the protection pattern may include indium gallium zinc oxide (IGZO).

In an embodiment, the display device may further include a functional layer disposed on the spacer, a common electrode disposed on the functional layer, and a capping layer disposed on the common electrode.

In an embodiment, each of the functional layer, the common electrode, and the capping layer may be disconnected on the spacer.

In an embodiment, each of the functional layer, the common electrode, and the capping layer may be disconnected by the side surface of the spacer.

In an embodiment, the display device may further include a sealing member disposed between the first substrate and the second substrate along an edge of each of the first substrate and the second substrate and coupling the first substrate and the second substrate.

In an embodiment, the second substrate may include a glass substrate.

A display device according to an embodiment of the present disclosure includes a first substrate defining a light emitting area and a non-light emitting area surrounding the light emitting area, a spacer disposed on the first substrate, overlapping the non-light emitting area in a plan view, and including a side surface having a reverse tapered shape in a cross-sectional view, a protection pattern disposed on the spacer and overlapping the non-light emitting area in a plan view, and a second substrate disposed on the protection pattern and spaced apart from the first substrate to define a space.

In an embodiment, the protection pattern may cover an upper surface and the side surface of the spacer.

In an embodiment, the light emitting area may include first light emitting areas that each emits first light, second light emitting areas that each emits second light, and third light emitting areas that each emits third light, and the spacer may be disposed between two of the third light emitting areas adjacent to each other.

In an embodiment, the space may be filled with a filler.

In an embodiment, the protection pattern may include an inorganic material.

In an embodiment, the protection pattern may include indium gallium zinc oxide (IGZO).

In an embodiment, the display device may further include a functional layer disposed on the spacer, a common electrode disposed on the functional layer, and a capping layer disposed on the common electrode.

In an embodiment, each of the functional layer, the common electrode, and the capping layer may overlap the light emitting area and the non-light emitting area in a plan view, and each of the functional layer, the common electrode, and the capping layer may be disconnected by the spacer.

In an embodiment, each of the functional layer, the common electrode, and the capping layer may be disconnected by the side surface of the spacer.

In an embodiment, the display device may further include a sub-spacer disposed on the first substrate, overlapping the non-light emitting area in a plan view, spaced apart from the spacer in a plan view, and having an area smaller than an area of the spacer in a plan view.

An electronic device according to an embodiment of the present disclosure includes a display device and a power module that supplies power to the display device. The display device includes a first substrate, a spacer disposed on the first substrate and including a side surface having a reverse tapered shape in a cross-sectional view, a protection pattern disposed on the spacer, and a second substrate disposed on the protection pattern and spaced apart from the first substrate to define a space.

In a display device according to embodiments of the present disclosure, the display device may include a spacer of which a side surface has a reverse tapered shape in a cross-sectional view. Upper components (e.g., functional layer, common electrode, or the like) disposed on the spacer may be disconnected by the shape of the spacer. Accordingly, even if the upper components disposed on an upper surface of the spacer are scratched, penetration of foreign substances or the like into light emitting elements may be prevented. In addition, the display device may include a protection pattern covering the spacer. The protection pattern may protect the spacer from impact, scratch, or the like. Accordingly, penetration of foreign substances or the like into the light emitting elements through the spacer may be prevented. Accordingly, since the light emitting elements may be protected by the spacer and the protection pattern, display quality of the display device may be improved.

### BRIEF DESCRIPTION OF THE DRAWINGS

FIG. 1 is a plan view illustrating a display device according to an embodiment of the present disclosure.

FIG. 2 is a cross-sectional view illustrating the display device of FIG. 1.

FIG. 3 is an enlarged plan view of a portion of a display area of the display device of FIG. 1.

FIG. 4 is a cross-sectional view taken along line I-I′ of FIG. 3.

FIG. 5 is a cross-sectional view illustrating a display device according to an embodiment of the present disclosure.

FIG. 6 is a block diagram illustrating an electronic device according to an embodiment of the present disclosure.

FIG. 7 is a schematic view illustrating electronic devices according to embodiments of the present disclosure.

### DETAILED DESCRIPTION OF THE EMBODIMENTS

Hereinafter, embodiments of the present disclosure will be described in more detail with reference to the accompanying drawings. The same reference numerals are used for the same components in the drawings, and redundant descriptions of the same components will be omitted.

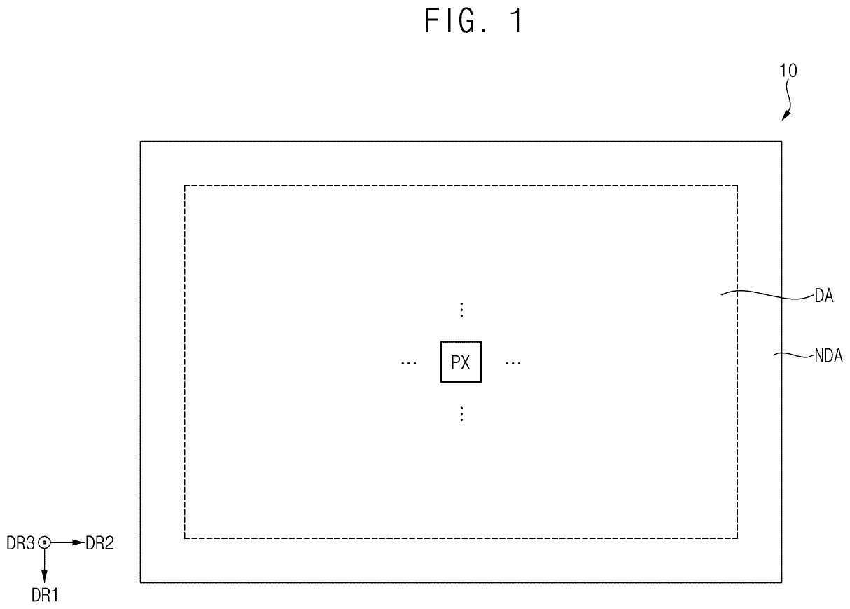

FIG. 1 is a plan view illustrating a display device according to an embodiment of the present disclosure.

Referring to FIG. 1, a display device 10 may include a display area DA and a non-display area NDA.

The display area DA may be an area that displays an image. Pixels PX may be disposed in the display area DA. The pixels PX may be disposed in a matrix form in a first direction DR1 and a second direction DR2 intersecting the first direction DR1. For example, the first direction DR1 may be perpendicular to the second direction DR2. Each of the pixels PX may emit light. As each of the pixels PX may emit light, the display area DA may display an image in a third direction DR3 intersecting each of the first direction DR1 and the second direction DR2. For example, the third direction DR3 may be perpendicular to each of the first direction DR1 and the second direction DR2. Lines connected to the pixels PX may be further disposed in the display area DA. For example, the lines may include a data signal line, a gate signal line, a power line, and the like.

The non-display area NDA may be an area that does not display an image. The non-display area NDA may be disposed around the display area DA. For example, the non-display area NDA may surround the display area DA in a plan view. Drivers for driving the pixels PX may be disposed in the non-display area NDA. For example, the drivers may include a data driver, a gate driver, a power voltage generator, a timing controller, or the like. The pixels PX may emit light based on signals received from the drivers.

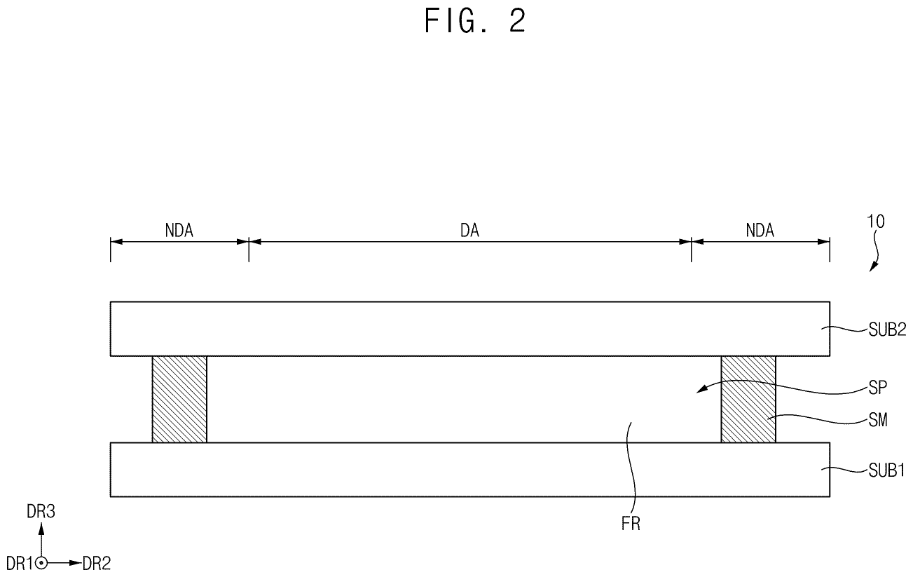

FIG. 2 is a cross-sectional view illustrating the display device of FIG. 1.

Referring to FIGS. 1 and 2, the display device 10 may include a first substrate SUB1, a second substrate SUB2, and a sealing member SM.

The first substrate SUB1 may include a transparent material or an opaque material. For example, the first substrate SUB1 may include a glass substrate, a polymer substrate, a flexible film, a metal substrate, or the like. These may be used alone or in combination with each other. In an embodiment, the first substrate SUB1 may include a glass substrate.

The second substrate SUB2 may be disposed on the first substrate SUB1. The second substrate SUB2 may face the first substrate SUB1. The second substrate SUB2 may be spaced apart from the first substrate SUB1 in the third direction DR3. Accordingly, a space SP may be defined between the first substrate SUB1 and the second substrate SUB2. In an embodiment, the space SP may be filled with a filler FR. For example, the filler FR may include an organic material such as silicone resin, epoxy resin, or the like, air, or the like. In addition, the filler FR may further include a material for matching a refractive index. In another embodiment, the space SP may be in a vacuum state.

The second substrate SUB2 may include a transparent material or an opaque material. For example, the second substrate SUB2 may include a glass substrate, a polymer substrate, a flexible film, a metal substrate, or the like. These may be used alone or in combination with each other. In an embodiment, the second substrate SUB2 may include a glass substrate.

The sealing member SM may be disposed between the first substrate SUB1 and the second substrate SUB2 along an edge of each of the first substrate SUB1 and the second substrate SUB2. The sealing member SM may be disposed between the first substrate SUB1 and the second substrate SUB2 along the non-display area NDA. The first substrate SUB1 and the second substrate SUB2 may be coupled by the sealing member SM. Since the space SP between the first substrate SUB1 and the second substrate SUB2 may be sealed by the sealing member SM, external moisture, air, impurities, or the like may be prevented from penetrating into the space SP. For example, the sealing member SM may include an organic material such as epoxy resin or the like.

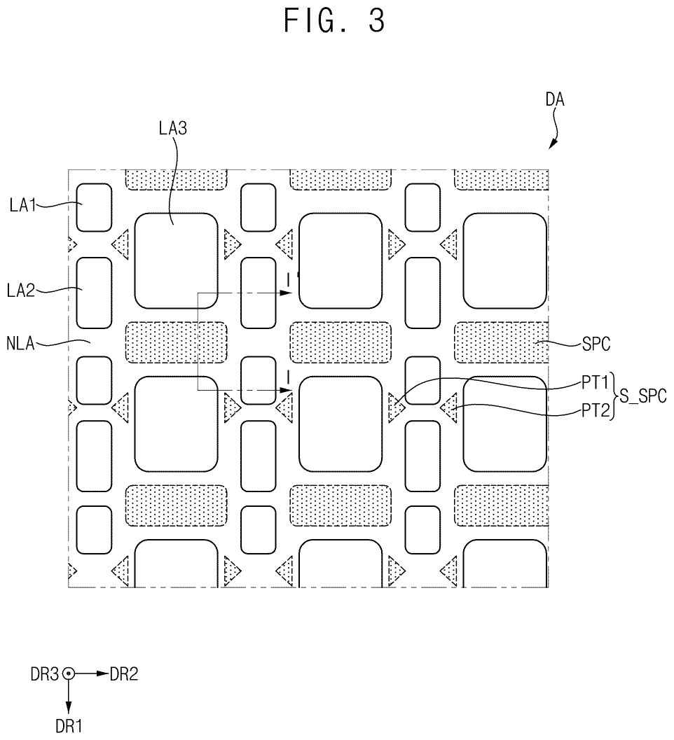

FIG. 3 is an enlarged plan view of a portion of a display area of the display device of FIG. 1.

Referring to FIGS. 1, 2, and 3, the display area DA of the display device 10 may include a light emitting area and a non-light emitting area NLA. The light emitting area may include first light emitting areas LA1, second light emitting areas LA2, and third light emitting areas LA3. Each of the first light emitting areas LA1, the second light emitting areas LA2, and the third light emitting areas LA3 may emit light. As each of the first light emitting areas LA1, the second light emitting areas LA2, and the third light emitting areas LA3 may emit light, the display area DA may display an image. The first, second, and third light emitting areas LA1, LA2, and LA3 may correspond to the pixels PX, respectively.

In an embodiment, the first light emitting areas LA1, the second light emitting areas LA2, and the third light emitting areas LA3 may emit light in different wavelength bands. Each of the first light emitting areas LA1 may emit first light, each of the second light emitting areas LA2 may emit second light, and each of the third light emitting areas LA3 may emit third light. For example, the first light may be light in a red wavelength band, the second light may be light in a green wavelength band, and the third light may be light in a blue wavelength band, but the present disclosure is not limited thereto. In another embodiment, the first light emitting areas LA1, the second light emitting areas LA2, and the third light emitting areas LA3 may emit light in the same wavelength band. In still another embodiment, at least one of the first light emitting areas LA1, the second light emitting areas LA2, and the third light emitting areas LA3 may emit light in a different wavelength band.

In an embodiment, the first light emitting areas LA1, the second light emitting areas LA2, and the third light emitting areas LA3 may be disposed in rows, each of which may extend in the second direction DR2. The first light emitting areas LA1 and the second light emitting areas LA2 may be disposed in first columns, each of which may extend in the first direction DR1. The third light emitting areas LA3 may be disposed in second columns, each of which may extend in the first direction DR1. The first and second columns may be disposed adjacent to each other and repeat in the second direction DR2, for example, a sequential arrangement of the first column, the second column, the first column, the second column, etc. However, the present disclosure is not limited thereto, and an arrangement structure of the first, second, and third light emitting areas LA1, LA2, and LA3 may be variously modified.

In an embodiment, the third light emitting areas LA3 may have an area larger than that of each of the first light emitting areas LA1 and the second light emitting areas LA2 in a plan view. The second light emitting areas LA2 may have an area larger than or equal to that of the first light emitting areas LA1 in a plan view. However, the present disclosure is not limited thereto, and the area of each of the first, second, and third light emitting areas LA1, LA2, and LA3 may be variously modified.

The non-light emitting area NLA may be an area that does not emit light. The non-light emitting area NLA may surround the light emitting area. That is, the non-light emitting area NLA may surround each of the first, second, and third light emitting areas LA1, LA2, and LA3. The non-light emitting area NLA may partition the first, second, and third light emitting areas LA1, LA2, and LA3.

The display device 10 may include a spacer SPC. The spacer SPC may be repeatedly disposed in the first direction DR1 and the second direction DR2 in the display area DA. In a plan view, the spacer SPC may overlap the non-light emitting area NLA, and may not overlap the light emitting area. In an embodiment, the spacer SPC may be disposed between third light emitting areas LA3 adjacent to each other among the third light emitting areas LA3. For example, the spacer SPC may be disposed between third light emitting areas LA3 adjacent to each other in the first direction DR1 among the third light emitting areas LA3. The spacer SPC and the third light emitting areas LA3 may be alternately disposed in the first direction DR1. However, the present disclosure is not limited thereto, and an arrangement structure of the spacer SPC may be variously modified.

The display device 10 may further include a sub-spacer S_SPC. The sub-spacer S_SPC may be repeatedly disposed in the first direction DR1 and the second direction DR2 in the display area DA. In a plan view, the sub-spacer S_SPC may overlap the non-light emitting area NLA, and may not overlap the light emitting area. The sub-spacer S_SPC may be spaced apart from the spacer SPC in a plan view. The sub-spacer S_SPC may be disposed in a portion of the non-light emitting area NLA, and the spacer SPC may be disposed in another portion of the non-light emitting area NLA. The sub-spacer S_SPC may have an area smaller than that of the spacer SPC in a plan view. However, the present disclosure is not limited thereto, and the area of each of the spacer SPC and the sub-spacer S_SPC may be variously modified.

The sub-spacer S_SPC may include a first portion PT1 and a second portion PT2 spaced apart from each other. For example, the second portion PT2 may be spaced apart from the first portion PT1 in the second direction DR2. The first portion PT1 and the second portion PT2 may be symmetrical with respect to an axis parallel to the first direction DR1. In an embodiment, the sub-spacer S_SPC may be disposed between third light emitting areas LA3 adjacent to each other among the third light emitting areas LA3. For example, the sub-spacer S_SPC may be disposed between third light emitting areas LA3 adjacent to each other in the second direction DR2 among the third light emitting areas LA3. The sub-spacer S_SPC and the third light emitting areas LA3 may be alternately disposed in the second direction DR2. However, the present disclosure is not limited thereto, and an arrangement structure of the sub-spacer S_SPC may be variously modified.

Each of the spacer SPC and the sub-spacer S_SPC may prevent display characteristics of the display device 10 from being deteriorated by an external impact or the like. Each of the spacer SPC and the sub-spacer S_SPC may serve to maintain the space SP between the first substrate SUB1 and the second substrate SUB2. In addition, each of the spacer SPC and the sub-spacer S_SPC may serve to support a fine metal mask (FMM) used to deposit a light emitting material.

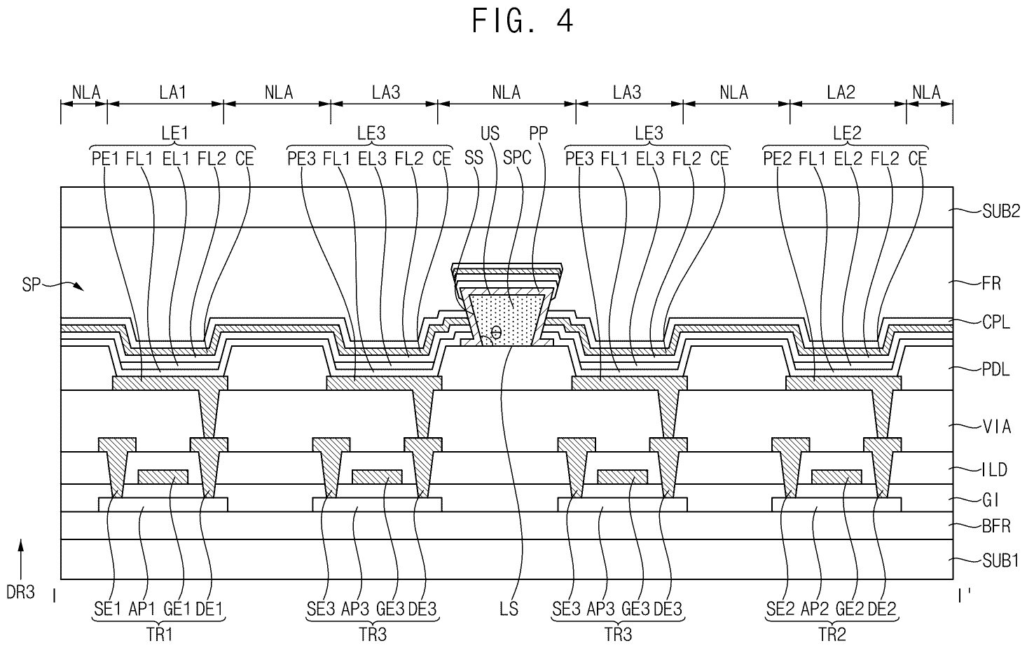

FIG. 4 is a cross-sectional view taken along line I-I′ of FIG. 3.

Referring to FIGS. 1, 3, and 4, the display device 10 may include the first substrate SUB1, a buffer layer BFR, first, second, and third transistors TR1, TR2, and TR3, a gate insulating layer GI, an interlayer insulating layer ILD, a via insulating layer VIA, first, second, and third light emitting elements LE1, LE2, and LE3, a pixel defining layer PDL, the spacer SPC, a protection pattern PP, a capping layer CPL, the filler FR, and the second substrate SUB2.

The first transistor TR1 may include a first active pattern AP1, a first gate electrode GE1, a first source electrode SE1, and a first drain electrode DE1, the second transistor TR2 may include a second active pattern AP2, a second gate electrode GE2, a second source electrode SE2, and a second drain electrode DE2, and the third transistor TR3 may include a third active pattern AP3, a third gate electrode GE3, a third source electrode SE3, and a third drain electrode DE3.

The first light emitting element LE1 may include a first pixel electrode PE1, a first functional layer FL1, a first light emitting layer EL1, a second functional layer FL2, and a common electrode CE, the second light emitting element LE2 may include a second pixel electrode PE2, the first functional layer FL1, a second light emitting layer EL2, the second functional layer FL2, and the common electrode CE, and the third light emitting element LE3 may include a third pixel electrode PE3, the first functional layer FL1, a third light emitting layer EL3, the second functional layer FL2, and the common electrode CE.

The buffer layer BFR may be disposed on the first substrate SUB1. The buffer layer BFR may prevent metal atoms or impurities from being diffused from the first substrate SUB1 to the first, second, and third transistors TR1, TR2, and TR3. In addition, the buffer layer BFR may improve a flatness of a surface of the first substrate SUB1 when the surface of the first substrate SUB1 is not uniform. The buffer layer BFR may include an inorganic material such as silicon oxide (SiOₓ), silicon nitride (SiNₓ), silicon oxynitride (SiOₓN_{y}), or the like. These may be used alone or in combination with each other.

The first, second, and third active patterns AP1, AP2, and AP3 may be disposed on the buffer layer BFR. Each of the first, second, and third active patterns AP1, AP2, and AP3 may include a source area, a drain area, and a channel area between the source area and the drain area. Each of the first, second, and third active patterns AP1, AP2, and AP3 may include a silicon semiconductor material or an oxide semiconductor material. Examples of the silicon semiconductor material may include amorphous silicon, polycrystalline silicon, and the like. Examples of the oxide semiconductor material may include indium gallium zinc oxide (IGZO), indium tin zinc oxide (ITZO), and the like. These may be used alone or in combination with each other.

The gate insulating layer GI may be disposed on the buffer layer BFR and the first, second, and third active patterns AP1, AP2, and AP3. The gate insulating layer GI may cover the first, second, and third active patterns AP1, AP2, and AP3. For example, the gate insulating layer GI may sufficiently cover the first, second, and third active patterns AP1, AP2, and AP3, and may have a substantially flat upper surface without generating a step difference around the first, second, and third active patterns AP1, AP2, and AP3. For another example, the gate insulating layer GI may cover the first, second, and third active patterns AP1, AP2, and AP3, and may be disposed along profiles of the first, second, and third active patterns AP1, AP2, and AP3 with a uniform thickness. The gate insulating layer GI may include an inorganic material such as silicon oxide, silicon nitride, silicon oxynitride, or the like. These may be used alone or in combination with each other.

The first, second, and third gate electrodes GE1, GE2, and GE3 may be disposed on the gate insulating layer GI. The first, second, and third gate electrodes GE1, GE2, and GE3 may overlap the channel areas of the first, second, and third active patterns AP1, AP2, and AP3, respectively, in a plan view. Each of the first, second, and third gate electrodes GE1, GE2, and GE3 may include a metal, an alloy, a conductive metal oxide, a conductive metal nitride, or the like. Examples of the metal may include silver (Ag), molybdenum (Mo), aluminum (Al), tungsten (W), copper (Cu), nickel (Ni), chromium (Cr), titanium (Ti), tantalum (Ta), platinum (Pt), scandium (Sc), or the like. Examples of the conductive metal oxide may include indium tin oxide (ITO), indium zinc oxide (IZO), or the like. Examples of the conductive metal nitride may include aluminum nitride (AlNₓ), tungsten nitride (WNₓ), chromium nitride (CrNₓ), or the like. These may be used alone or in combination with each other.

The interlayer insulating layer ILD may be disposed on the gate insulating layer GI and the first, second, and third gate electrodes GE1, GE2, and GE3. The interlayer insulating layer ILD may cover the first, second, and third gate electrodes GE1, GE2, and GE3. For example, the interlayer insulating layer ILD may sufficiently cover the first, second, and third gate electrodes GE1, GE2, and GE3, and may have a substantially flat upper surface without generating a step difference around the first, second, and third gate electrodes GE1, GE2, and GE3. For another example, the interlayer insulating layer ILD may cover the first, second, and third gate electrodes GE1, GE2, and GE3, and may be disposed along profiles of the first, second, and third gate electrodes GE1, GE2, and GE3 with a uniform thickness. The interlayer insulating layer ILD may include an inorganic material such as silicon oxide, silicon nitride, silicon oxynitride, or the like. These may be used alone or in combination with each other.

The first, second, and third source electrodes SE1, SE2, and SE3 and the first, second, and third drain electrodes DE1, DE2, and DE3 may be disposed on the interlayer insulating layer ILD. Each of the first, second, and third source electrodes SE1, SE2, and SE3 and the first, second, and third drain electrodes DE1, DE2, and DE3 may include a metal, an alloy, a conductive metal oxide, a conductive metal nitride, or the like. These may be used alone or in combination with each other.

The first, second, and third source electrodes SE1, SE2, and SE3 may be connected to the first, second, and third active patterns AP1, AP2, and AP3, respectively. For example, the first, second, and third source electrodes SE1, SE2, and SE3 may be in contact with the source areas of the first, second, and third active patterns AP1, AP2, and AP3, respectively. In addition, the first, second, and third drain electrodes DE1, DE2, and DE3 may be connected to the first, second, and third active patterns AP1, AP2, and AP3, respectively. For example, the first, second, and third drain electrodes DE1, DE2, and DE3 may be in contact with the drain areas of the first, second, and third active patterns AP1, AP2, and AP3, respectively.

The via insulating layer VIA may be disposed on the interlayer insulating layer ILD, the first, second, and third source electrodes SE1, SE2, and SE3, and the first, second, and third drain electrodes DE1, DE2, and DE3. The via insulating layer VIA may sufficiently cover the first, second, and third source electrodes SE1, SE2, and SE3 and the first, second, and third drain electrodes DE1, DE2, and DE3. The via insulating layer VIA may include an organic material such as phenol resin, acrylic resin, polyimide resin, polyamide resin, siloxane resin, epoxy resin, or the like. These may be used alone or in combination with each other.

The first, second, and third pixel electrodes PE1, PE2, and PE3 may be disposed on the via insulating layer VIA. The first, second, and third pixel electrodes PE1, PE2, and PE3 may overlap the first, second, and third light emitting areas LA1, LA2, and LA3, respectively, in a plan view. The first, second, and third pixel electrodes PE1, PE2, and PE3 may be connected to the first, second, and third transistors TR1, TR2, and TR3, respectively. For example, the first, second, and third pixel electrodes PE1, PE2, and PE3 may be in contact with the first, second, and third drain electrodes DE1, DE2, and DE3 or the first, second, and third source electrodes SE1, SE2, and SE3 through contact holes formed in the via insulating layer VIA, respectively. Each of the first, second, and third pixel electrodes PE1, PE2, and PE3 may include a metal, an alloy, a conductive metal oxide, a conductive metal nitride, a transparent conductive material, or the like. These may be used alone or in combination with each other.

The pixel defining layer PDL may be disposed on the via insulating layer VIA. The pixel defining layer PDL may expose at least a portion of an upper surface of each of the first, second, and third pixel electrodes PE1, PE2, and PE3. For example, the pixel defining layer PDL may cover a side surface of each of the first, second, and third pixel electrodes PE1, PE2, and PE3. For example, the pixel defining layer PDL may include an organic material such as polyimide resin, epoxy resin, siloxane resin, or the like, or an inorganic material such as silicon oxide, silicon nitride, silicon oxynitride, or the like. These may be used alone or in combination with each other. For another example, the pixel defining layer PDL may include an organic material or an inorganic material including a light blocking material having a black color.

The pixel defining layer PDL may overlap the non-light emitting area NLA in a plan view. The first, second, and third light emitting areas LA1, LA2, and LA3 may be defined respectively corresponding to areas of the first, second, and third pixel electrodes PE1, PE2, and PE3 exposed by the pixel defining layer PDL. The non-light emitting area NLA may be defined between the first, second, and third light emitting areas LA1, LA2, and LA3.

The spacer SPC may be disposed on the pixel defining layer PDL. The spacer SPC may overlap the non-light emitting area NLA in a plan view. For example, the spacer SPC may be disposed between the third light emitting areas LA3 adjacent to each other. That is, the spacer SPC may be disposed on the pixel defining layer PDL overlapping the non-light emitting area NLA between the third light emitting areas LA3 adjacent to each other. The spacer SPC may protrude from an upper surface of the pixel defining layer PDL in a thickness direction (e.g., the third direction DR3). For example, the spacer SPC may be formed through a separate process from the pixel defining layer PDL. The spacer SPC may include a material different from that of the pixel defining layer PDL.

In an embodiment, the spacer SPC may have a reverse tapered shape in a cross-sectional view. The spacer SPC may include a side surface SS having a reverse tapered shape in a cross-sectional view. The spacer SPC may be formed through a photolithography process. In this case, the spacer SPC may include a negative type organic material, and accordingly, the spacer SPC of which the side surface SS has the reverse tapered shape may be formed.

The spacer SPC may have a lower surface LS that faces the first substrate SUB1 and an upper surface US that faces away from the first substrate SUB1. The upper surface US may be wider than the lower surface LS. The upper surface US wider than the lower surface LS may define the reverse tapered shape of the side surface SS of the spacer SPC. The side surface SS of the spacer SPC may be at an oblique angle θ with respect to the lower surface LS. The reverse tapered shape of the side surface SS may have the oblique angle θ with respect to the lower surface LS.

The protection pattern PP may be disposed on the spacer SPC. The protection pattern PP may overlap the non-light emitting area NLA in a plan view. The protection pattern PP may cover the upper surface US and the side surface SS of the spacer SPC. As the protection pattern PP may entirely cover the spacer SPC, the spacer SPC may be protected. For example, the protection pattern PP may protect the spacer SPC from being scratched by the second substrate SUB2, the fine metal mask, or the like. As the protection pattern PP may protect the spacer SPC from impact, scratch, or the like, penetration of foreign substances (e.g., the filler FR) or the like through the spacer SPC may be minimized.

In an embodiment, the protection pattern PP may include an inorganic material such as silicon oxide, silicon nitride, silicon oxynitride, or the like. In another embodiment, the protection pattern PP may include an oxide semiconductor material such as indium gallium zinc oxide or the like. These may be used alone or in combination with each other. However, the present disclosure is not limited thereto, and the protection pattern PP may include various materials that protect the spacer SPC from impact or the like.

The first functional layer FL1 may be disposed on the first, second, and third pixel electrodes PE1, PE2, and PE3, the pixel defining layer PDL, and the protection pattern PP. The first functional layer FL1 may overlap the first, second, and third light emitting areas LA1, LA2, and LA3 and the non-light emitting area NLA in a plan view. That is, the first functional layer FL1 may be entirely disposed in the display area DA. The first functional layer FL1 may have a single layer structure or a multi-layer structure. For example, the first functional layer FL1 may include at least one of a hole injection layer and a hole transport layer.

In an embodiment, the first functional layer FL1 may be disconnected on the spacer SPC. The first functional layer FL1 may be disconnected in the non-light emitting area NLA by the side surface SS of the spacer SPC. That is, as the spacer SPC may have the reverse tapered shape, the first functional layer FL1 may not extend continuously in the non-light emitting area NLA in which the spacer SPC is disposed, and may be disconnected by the spacer SPC.

The first, second, and third light emitting layers EL1, EL2, and EL3 may be disposed on the first, second, and third pixel electrodes PE1, PE2, and PE3, respectively. The first, second, and third light emitting layers EL1, EL2, and EL3 may be disposed on the first, second, and third pixel electrodes PE1, PE2, and PE3 exposed by the pixel defining layer PDL, respectively. That is, the first, second, and third light emitting layers EL1, EL2, and EL3 may overlap the first, second, and third light emitting areas LA1, LA2, and LA3, respectively, in a plan view.

The first light emitting layer EL1 may emit the first light, and may include an organic material that emits the first light. The second light emitting layer EL2 may emit the second light, and may include an organic material that emits the second light. The third light emitting layer EL3 may emit the third light, and may include an organic material that emits the third light. For example, the first light may be light in a red wavelength band, the second light may be light in a green wavelength band, and the third light may be light in a blue wavelength band, but the present disclosure is not limited thereto.

The second functional layer FL2 may be disposed on the first functional layer FL1 and the first, second, and third light emitting layers EL1, EL2, and EL3. The second functional layer FL2 may overlap the first, second, and third light emitting areas LA1, LA2, and LA3 and the non-light emitting area NLA in a plan view. That is, the second functional layer FL2 may be entirely disposed in the display area DA. The second functional layer FL2 may have a single layer structure or a multi-layer structure. For example, the second functional layer FL2 may include at least one of an electron injection layer and an electron transport layer.

In an embodiment, the second functional layer FL2 may be disconnected on the spacer SPC. The second functional layer FL2 may be disconnected in the non-light emitting area NLA by the side surface SS of the spacer SPC. That is, as the spacer SPC may have the reverse tapered shape, the second functional layer FL2 may not extend continuously in the non-light emitting area NLA in which the spacer SPC is disposed, and may be disconnected by the spacer SPC.

The common electrode CE may be disposed on the second functional layer FL2. The common electrode CE may overlap the first, second, and third light emitting areas LA1, LA2, and LA3 and the non-light emitting area NLA in a plan view. That is, the common electrode CE may be entirely disposed in the display area DA. The common electrode CE may include a metal, an alloy, a conductive metal oxide, a conductive metal nitride, a transparent conductive material, or the like. These may be used alone or in combination with each other.

In an embodiment, the common electrode CE may be disconnected on the spacer SPC. The common electrode CE may be disconnected in the non-light emitting area NLA by the side surface SS of the spacer SPC. That is, as the spacer SPC may have the reverse tapered shape, the common electrode CE may not extend continuously in the non-light emitting area NLA in which the spacer SPC is disposed, and may be disconnected by the spacer SPC.

Accordingly, the first light emitting element LE1 including the first pixel electrode PE1, the first light emitting layer EL1, the first and second functional layers FL1 and FL2, and the common electrode CE may be disposed in the first light emitting area LA1 on the first substrate SUB1. The second light emitting element LE2 including the second pixel electrode PE2, the second light emitting layer EL2, the first and second functional layers FL1 and FL2, and the common electrode CE may be disposed in the second light emitting area LA2 on the first substrate SUB1. The third light emitting element LE3 including the third pixel electrode PE3, the third light emitting layer EL3, the first and second functional layers FL1 and FL2, and the common electrode CE may be disposed in the third light emitting area LA3 on the first substrate SUB1. The first, second, and third light emitting elements LE1, LE2, and LE3 may be electrically connected to the first, second, and third transistors TR1, TR2, and TR3, respectively.

The capping layer CPL may be disposed on the common electrode CE. The capping layer CPL may protect the common electrode CE. The capping layer CPL may overlap the first, second, and third light emitting areas LA1, LA2, and LA3 and the non-light emitting area NLA in a plan view. That is, the capping layer CPL may be entirely disposed in the display area DA. The capping layer CPL may include an inorganic material such as silicon oxide, silicon nitride, silicon oxynitride, or an organic material such as polyimide resin, epoxy resin, siloxane resin, or the like.

In an embodiment, the capping layer CPL may be disconnected on the spacer SPC. The capping layer CPL may be disconnected in the non-light emitting area NLA by the side surface SS of the spacer SPC. That is, as the spacer SPC may have the reverse tapered shape, the capping layer CPL may not extend continuously in the non-light emitting area NLA in which the spacer SPC is disposed, and may be disconnected by the spacer SPC.

As upper components disposed on the spacer SPC (e.g., the first and second functional layers FL1 and FL2, the common electrode CE, and the capping layer CPL disposed on the spacer SPC) may be disconnected by the spacer SPC, the first, second, and third light emitting elements LE1, LE2, and LE3 may be protected from penetration of foreign substances (e.g., the filler FR) or the like due to scratches of the upper components by the second substrate SUB2, the fine metal mask, or the like.

When the upper components are extended without being disconnected in the first, second, and third light emitting areas LA1, LA2, and LA3 and the non-light emitting area NLA, penetration of foreign substances (e.g., the filler FR) or the like into the first, second, and third light emitting layers EL1, EL2, and EL3 or the first and second functional layers FL1 and FL2 overlapping the first, second, and third light emitting areas LA1, LA2, and LA3 may occur due to scratches of the upper components disposed on the upper surface US of the spacer SPC. In this case, dark spots, stains, or the like may occur in the first, second, and third light emitting areas LA1, LA2, and LA3, and display quality of the display device 10 may be deteriorated.

On the other hand, when the upper components are disconnected by the spacer SPC in the non-light emitting area NLA, even if the upper components disposed on the upper surface US of the spacer SPC are scratched, a penetration path of the foreign substances (e.g., the filler FR) or the like into the first, second, and third light emitting layers EL1, EL2, and EL3 or the first and second functional layers FL1 and FL2 overlapping the first, second, and third light emitting areas LA1, LA2, and LA3 may be blocked. Accordingly, the first, second, and third light emitting elements LE1, LE2, and LE3 may be protected, and reliability of the display device 10 may be improved.

The second substrate SUB2 may be spaced apart from the capping layer CPL in the third direction DR3. The space SP may be defined between the capping layer CPL and the second substrate SUB2. In an embodiment, the space SP may be filled with the filler FR.

Although FIG. 4 illustrates only a cross-sectional structure of the spacer SPC, the spacer SPC may correspond to the sub-spacer S_SPC. Therefore, the sub-spacer S_SPC may include a side surface having a reverse tapered shape in a cross-sectional view, and a protection pattern covering the sub-spacer S_SPC may be disposed on the sub-spacer S_SPC. In addition, upper components disposed on the sub-spacer S_SPC may be disconnected on the sub-spacer S_SPC.

In the display device 10 according to an embodiment of the present disclosure, the display device 10 may include the spacer SPC of which the side surface SS has the reverse tapered shape in a cross-sectional view. The upper components disposed on the spacer SPC may be disconnected by the shape of the spacer SPC. Accordingly, even if the upper components disposed on the upper surface US of the spacer SPC are scratched, the penetration of the foreign substances (e.g., the filler FR) or the like into the first, second, and third light emitting elements LE1, LE2, and LE3 may be prevented. In addition, the display device 10 may include the protection pattern PP covering the spacer SPC. The protection pattern PP may protect the spacer SPC from impact, scratch, or the like. Accordingly, the penetration of the foreign substances (e.g., the filler FR) or the like into the first, second, and third light emitting elements LE1, LE2, and LE3 through the spacer SPC may be prevented. Accordingly, display quality of the display device 10 may be improved.

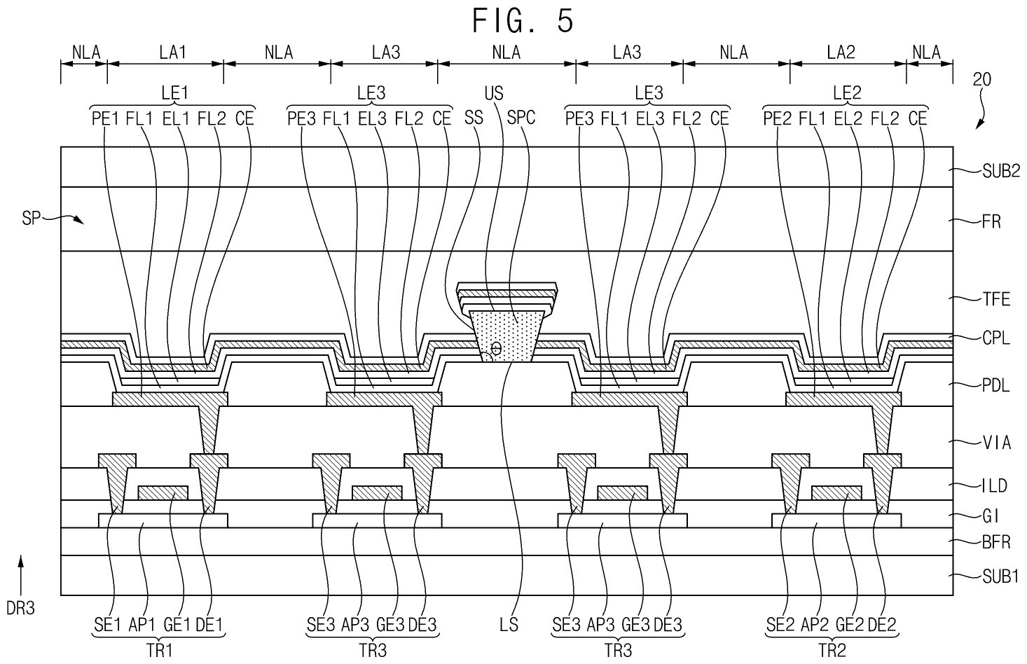

FIG. 5 is a cross-sectional view illustrating a display device according to an embodiment of the present disclosure. For example, FIG. 5 may correspond to the cross-sectional view of FIG. 4.

Hereinafter, descriptions overlapping the display device 10 described with reference to FIGS. 1, 2, 3, and 4 will be omitted or simplified.

Referring to FIG. 5, a display device 20 may include a first substrate SUB1, a buffer layer BFR, first, second, and third transistors TR1, TR2, and TR3, a gate insulating layer GI, an interlayer insulating layer ILD, a via insulating layer VIA, first, second, and third light emitting elements LE1, LE2, and LE3, a pixel defining layer PDL, a spacer SPC, a capping layer CPL, an encapsulation layer TFE, a filler FR, and a second substrate SUB2.

The first transistor TR1 may include a first active pattern AP1, a first gate electrode GE1, a first source electrode SE1, and a first drain electrode DE1, the second transistor TR2 may include a second active pattern AP2, a second gate electrode GE2, a second source electrode SE2, and a second drain electrode DE2, and the third transistor TR3 may include a third active pattern AP3, a third gate electrode GE3, a third source electrode SE3, and a third drain electrode DE3.

The first light emitting element LE1 may include a first pixel electrode PE1, a first functional layer FL1, a first light emitting layer EL1, a second functional layer FL2, and a common electrode CE, the second light emitting element LE2 may include a second pixel electrode PE2, the first functional layer FL1, a second light emitting layer EL2, the second functional layer FL2, and the common electrode CE, and the third light emitting element LE3 may include a third pixel electrode PE3, the first functional layer FL1, a third light emitting layer EL3, the second functional layer FL2, and the common electrode CE.

The buffer layer BFR, the first, second, and third active patterns AP1, AP2, and AP3, the gate insulating layer GI, the first, second, and third gate electrodes GE1, GE2, and GE3, the interlayer insulating layer ILD, the first, second, and third source electrodes SE1, SE2, and SE3, the first, second, and third drain electrodes DE1, DE2, and DE3, the via insulating layer VIA, the first, second, and third pixel electrodes PE1, PE2, and PE3, the pixel defining layer PDL, the spacer SPC, the first functional layer FL1, the first, second, and third light emitting layers EL1, EL2, and EL3, the second functional layer FL2, the common electrode CE, and the capping layer CPL may be sequentially disposed on the first substrate SUB1.

The spacer SPC may overlap a non-light emitting area NLA in a plan view. For example, the spacer SPC may be disposed in the non-light emitting area NLA between third light emitting areas LA3 adjacent to each other.

In an embodiment, the spacer SPC may have a reverse tapered shape in a cross-sectional view. That is, the spacer SPC may include a side surface SS having a reverse tapered shape in a cross-sectional view. The spacer SPC may be formed through a photolithography process. In this case, the spacer SPC may include a negative type organic material, and accordingly, the spacer SPC of which the side surface SS has the reverse tapered shape may be formed.

In an embodiment, upper components disposed on the spacer SPC (e.g., the first and second functional layers FL1 and FL2, the common electrode CE, and the capping layer CPL disposed on the spacer SPC) may be disconnected on the spacer SPC. The upper components may be disconnected in the non-light emitting area NLA by the side surface SS of the spacer SPC. That is, as the spacer SPC may have the reverse tapered shape, the upper components may not extend continuously in the non-light emitting area NLA in which the spacer SPC is disposed, and may be disconnected by the spacer SPC.

As the upper components may be disconnected by the spacer SPC, even if the upper components are scratched by the second substrate SUB2, a mask, or the like, a penetration path of foreign substances (e.g., the filler FR) or the like into the first, second, and third light emitting layers EL1, EL2, and LA3 or the first and second functional layers FL1 and FL2 overlapping the first, second, and third light emitting areas LA1, LA2, and LA3 may be blocked. Accordingly, the first, second, and third light emitting elements LE1, LE2, and LE3 may be protected, and reliability of the display device 20 may be improved.

The encapsulation layer TFE may be disposed on the capping layer CPL. The encapsulation layer TFE may cover the capping layer CPL and lower components. The encapsulation layer TFE may prevent impurities, moisture, external air, or the like from penetrating into the first, second, and third light emitting elements LE1, LE2, and LE3 from outside. For example, the encapsulation layer TFE may include at least one inorganic encapsulation layer and at least one organic encapsulation layer.

The encapsulation layer TFE may cover an upper surface US and the side surface SS of the spacer SPC. As the encapsulation layer TFE may entirely cover the lower components including the spacer SPC, the spacer SPC and the upper components disposed on the spacer SPC may be protected. For example, the encapsulation layer TFE may prevent the spacer SPC from being scratched by the second substrate SUB2, the mask, or the like. As the encapsulation layer TFE may protect the spacer SPC from impact, scratch, or the like, penetration of the foreign substances (e.g., the filler FR) or the like through the spacer SPC may be minimized.

The second substrate SUB2 may be spaced apart from the encapsulation layer TFE in a third direction DR3. A space SP may be defined between the second substrate SUB2 and the encapsulation layer TFE. In an embodiment, the space SP may be filled with the filler FR.

In the display device 20 according to an embodiment of the present disclosure, the display device 20 may include the spacer SPC of which the side surface SS has the reverse tapered shape in a cross-sectional view. The upper components disposed on the spacer SPC may be disconnected by the shape of the spacer SPC. Accordingly, even if the upper components disposed on the upper surface US of the spacer SPC are scratched, the penetration of the foreign substances (e.g., the filler FR) or the like into the first, second, and third light emitting elements LE1, LE2, and LE3 may be prevented. In addition, the display device 10 may include the encapsulation layer TFE covering the spacer SPC. The encapsulation layer TFE may protect the spacer SPC from impact, scratch, or the like. Accordingly, the penetration of the foreign substances (e.g., the filler FR) or the like into the first, second, and third light emitting elements LE1, LE2, and LE3 through the spacer SPC may be prevented. Accordingly, display quality of the display device 20 may be improved.

The display devices 10 and 20 according to embodiments of the present disclosure may be applied to various electronic devices. An electronic device according to an embodiment of the present disclosure may include the display device 10 or the display device 20 described above, and may further include a module or device having additional functions in addition to the display device 10 or the display device 20.

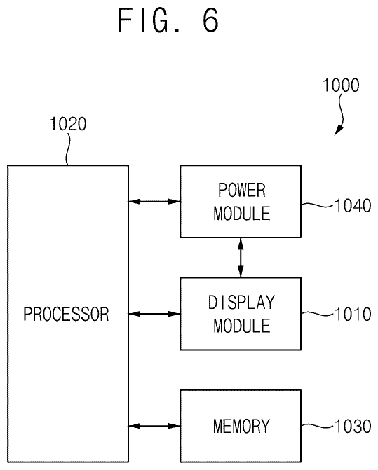

FIG. 6 is a block diagram illustrating an electronic device according to an embodiment of the present disclosure.

Referring to FIG. 6, an electronic device 1000 may include a display module 1010, a processor 1020, a memory 1030, and a power module 1040.

The processor 1020 may include at least one of a central processing unit (CPU), an application processor (AP), a graphic processing unit (GPU), a communication processor (CP), an image signal processor (ISP), and a controller.

The memory 1030 may store data information necessary for an operation of the processor 1020 or the display module 1010. When the processor 1020 executes an application stored in the memory 1030, an image data signal and/or an input control signal may be transmitted to the display module 1010, and the display module 1010 may process the received signal and output image information through a display screen.

The power module 1040 may include a power supply module such as a power adapter, a battery device, or the like and a power conversion module that converts power supplied by the power supply module to generate power necessary for an operation of the electronic device 1000.

At least one of the components of the electronic device 1000 described above may be included in the display device according to embodiments described above. In addition, some of individual modules functionally included in one module may be included in the display device, and others may be provided separately from the display device. For example, the display device may include the display module 1010, and the processor 1020, the memory 1030, and the power module 1040 may be provided in form of other devices in the electronic device 1000 other than the display device.

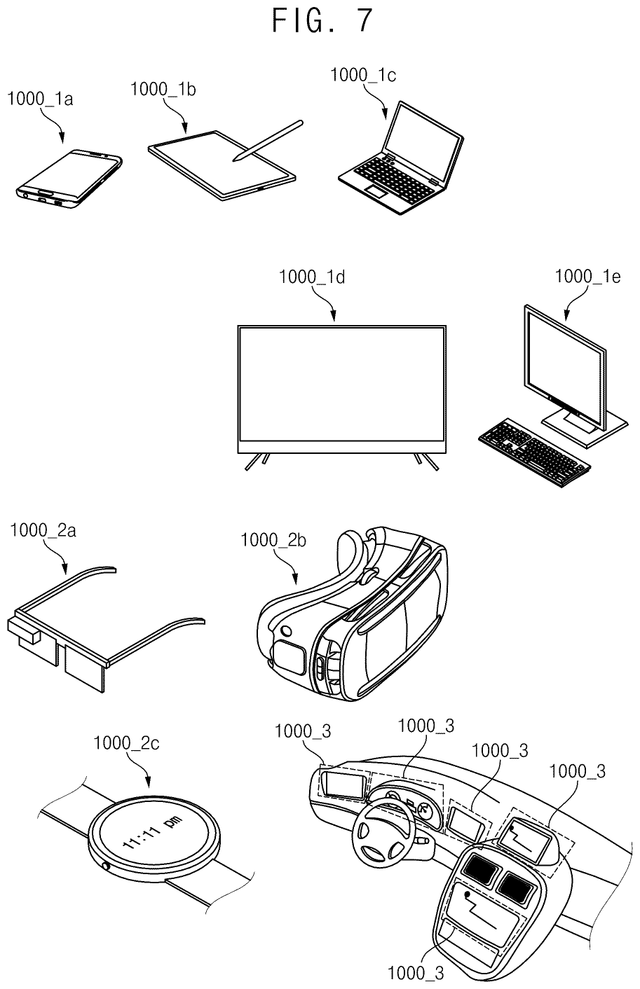

FIG. 7 is a schematic view illustrating electronic devices according to embodiments of the present disclosure.

Referring to FIG. 7, various electronic devices to which the display device according to embodiments of the present disclosure is applied may include not only an image display electronic device, but also a wearable electronic device including a display module, a vehicle electronic device 1000_3 including a display module, or the like. The image display electronic device may be a smartphone 1000_1a, a tablet PC 1000_1b, a laptop 1000_1c, a TV 1000_1d, a desk monitor 1000_1e, or the like. The wearable electronic device may be smart glasses 1000_2a, a head mounted display 1000_2b, a smart watch 1000_2c, or the like. The vehicle electronic device 1000_3 may be a center information display (CID) disposed on a dashboard and center fascia of a vehicle, a room mirror display, or the like.

The present disclosure can be applied to various display devices and electronic devices. For example, the present disclosure is applicable to various display devices such as display devices for vehicles, ships and aircraft, portable communication devices, display devices for exhibition or information transmission, medical display devices, and the like.

The foregoing is illustrative of embodiments and is not to be construed as limiting thereof. Although embodiments have been described, those skilled in the art will readily appreciate that many modifications are possible in the embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a first substrate;
a spacer disposed on the first substrate and including a side surface having a reverse tapered shape in a cross-sectional view;
a protection pattern disposed on the spacer; and
a second substrate disposed on the protection pattern and spaced apart from the first substrate to define a space.

2. The display device of claim 1, wherein the protection pattern covers an upper surface and the side surface of the spacer.

3. The display device of claim 1, wherein the space is filled with a filler.

4. The display device of claim 1, wherein the protection pattern includes an inorganic material.

5. The display device of claim 1, wherein the protection pattern includes indium gallium zinc oxide (IGZO).

6. The display device of claim 1, further comprising:
a functional layer disposed on the spacer;
a common electrode disposed on the functional layer; and
a capping layer disposed on the common electrode.

7. The display device of claim 6, wherein each of the functional layer, the common electrode, and the capping layer is disconnected on the spacer.

8. The display device of claim 7, wherein each of the functional layer, the common electrode, and the capping layer is disconnected by the side surface of the spacer.

9. The display device of claim 1, further comprising:
a sealing member disposed between the first substrate and the second substrate along an edge of each of the first substrate and the second substrate and coupling the first substrate and the second substrate.

10. The display device of claim 1, wherein the second substrate includes a glass substrate.

11. A display device comprising:
a first substrate defining a light emitting area and a non-light emitting area surrounding the light emitting area;
a spacer disposed on the first substrate, overlapping the non-light emitting area in a plan view, and including a side surface having a reverse tapered shape in a cross-sectional view;
a protection pattern disposed on the spacer and overlapping the non-light emitting area in a plan view; and
a second substrate disposed on the protection pattern and spaced apart from the first substrate to define a space.

12. The display device of claim 11, wherein the protection pattern covers an upper surface and the side surface of the spacer.

13. The display device of claim 11, wherein the light emitting area includes:
first light emitting areas that each emits first light;
second light emitting areas that each emits second light; and
third light emitting areas that each emits third light, and
wherein the spacer is disposed between two of the third light emitting areas adjacent to each other.

14. The display device of claim 11, wherein the space is filled with a filler.

15. The display device of claim 11, wherein the protection pattern includes an inorganic material.

16. The display device of claim 11, wherein the protection pattern includes indium gallium zinc oxide (IGZO).

17. The display device of claim 11, further comprising:
a functional layer disposed on the spacer;
a common electrode disposed on the functional layer; and
a capping layer disposed on the common electrode.

18. The display device of claim 17, wherein each of the functional layer, the common electrode, and the capping layer overlaps the light emitting area and the non-light emitting area in a plan view, and
each of the functional layer, the common electrode, and the capping layer is disconnected by the spacer.

19. The display device of claim 18, wherein each of the functional layer, the common electrode, and the capping layer is disconnected by the side surface of the spacer.

20. The display device of claim 11, further comprising:
a sub-spacer disposed on the first substrate, overlapping the non-light emitting area in a plan view, spaced apart from the spacer in a plan view, and having an area smaller than an area of the spacer in a plan view.

21. An electronic device comprising:
a display device; and
a power module that supplies power to the display device,
wherein the display device includes:
a first substrate;
a spacer disposed on the first substrate and including a side surface having a reverse tapered shape in a cross-sectional view;
a protection pattern disposed on the spacer; and
a second substrate disposed on the protection pattern and spaced apart from the first substrate to define a space.
